(19) United States
(12) Patent Application Publication
(10) Pub. No.: US 2025/0183187 A1
(43) Pub. Date: Jun. 5, 2025

(54) ELECTRONIC DEVICE

(71) Applicant: DENSO CORPORATION, Kariya-city (JP)

(72) Inventors: Tetsuya OKI, Kariya-city (JP); Yuichiro SASAKI, Kariya-city (JP); Akira TANIMOTO, Kariya-city (JP); Shingo TADA, Kariya-city (JP)

(21) Appl. No.: 18/953,230

(22) Filed: Nov. 20, 2024

(30) Foreign Application Priority Data
Dec. 5, 2023 (JP) 2023-205448

(51) Int. Cl. H01L 23/538; H01L 23/00

(52) U.S. Cl. CPC H01L 23/5386; H01L 23/5385; H01L 24/16; H01L 2224/16227

(57) ABSTRACT

An electronic device includes a board, an electronic component, and a solder disposed between lands of the board and terminals of the electronic component to bond therebetween. The board includes an insulating base and conductors disposed on the insulating base. The conductors include the lands, wirings disposed in layers, and interlayer connection portions electrically connecting the wirings on different layers. The lands include a first land to which the interlayer connection portions are electrically connected and a second land disposed adjacent to the first land and at a position below which no interlayer connection portion is disposed in a thickness direction of the board. The interlayer connection portions electrically connected to the first land include at least one interlayer connection portion that is disposed at a position offset from the first land so as not to overlap with the first land in the thickness direction.

### CROSS REFERENCE TO RELATED APPLICATION

The present application claims the benefit of priority from Japanese Patent Application No. 2023-205448 filed on Dec. 5, 2023, and the entire disclosures of which are incorporated herein by reference.

### TECHNICAL FIELD

The present disclosure relates to an electronic device.

### BACKGROUND

JP 2000-307023 A discloses an electronic device. The disclosure of JP 2000-307023 A is incorporated herein by reference as an explanation of technical elements in the present disclosure.

### SUMMARY

The present disclosure describes an electronic device including a board having lands on a surface thereof, an electronic component having terminals on a surface thereof facing the board, and a solder disposed between the lands of the board and the terminals of the electronic component to bond therebetween.

### BRIEF DESCRIPTION OF DRAWINGS

Objects, features and advantages of the present disclosure will become more apparent from the following detailed description made with reference to the accompanying drawings, in which:

FIG. 1 is a plan view of an electronic device according to a first embodiment;

FIG. 2 is a cross-sectional view of the electronic device taken along a line II-II in FIG. 1;

FIG. 3 is an enlarged plan view of a region III in FIG. 1;

FIG. 4 is a cross-sectional view of the electronic device taken along a line IV-IV in FIG. 3;

FIG. 5 is a cross-sectional view of an electronic device, as a reference example, when reflow is repeated multiple times;

FIG. 6 is a cross-sectional view of the electronic device according to the first embodiment, when reflow is repeated multiple times;

FIG. 7 is a cross-sectional view of a modification;

FIG. 8 is a cross-sectional view of a modification;

FIG. 9 is a plan view of an electronic device according to a second embodiment;

FIG. 10 is a cross sectional view taken along a line X-X in FIG. 9;

FIG. 11 is a plan view showing an arrangement of lands and via holes in an electronic device according to a third embodiment;

FIG. 12 is a plan view of a modification; and

FIG. 13 is a plan view showing an arrangement of lands and via holes in an electronic device according to a fourth embodiment.

### DETAILED DESCRIPTION

For example, there is an electronic device in which ball-shaped solders (solder bumps) are interposed between lands (pads) of a board (printed wiring board) and terminals of an electronic component to join the lands and the terminals. In such a configuration, if thermal expansion coefficients (linear expansion coefficients) of the portions directly below the lands that are adjacent to each other on the board are different, the solders will be separated when the reflow is repeated multiple times. This solder separation is sometimes called ball drop. In the viewpoint described above, or in another viewpoint not mentioned, further improvements are required in electronic devices.

The present disclosure provides an electronic device capable of suppressing solder separation.

According to an aspect of the present disclosure, an electronic device includes a board, an electronic component, and a solder. The board has a plurality of lands on a surface thereof. The electronic component is disposed on the board and has a plurality of terminals on a surface facing the surface of the board, the plurality of terminals being correspondingly provided for the plurality of lands. The solder is disposed between the plurality of lands and the plurality of terminals to bond therebetween. The board includes an insulating base and a plurality of conductors disposed on the insulating base. The plurality of conductors includes the plurality of lands, a plurality of wirings disposed in layers, and a plurality of interlayer connection portions electrically connecting the plurality of wirings on different layers. The plurality of lands includes a first land to which the interlayer connection portions are electrically connected and a second land that is disposed adjacent to the first land and at a position below which no interlayer connection portion is disposed in a thickness direction of the board. The interlayer connection portions electrically connected to the first land includes at least one interlayer connection portion that is disposed at a position offset from the first land so as not to overlap with the first land in the thickness direction.

In the electronic device having the configuration described above, at least one of the interlayer connection portions electrically connected to the first land is intentionally shifted to a position without overlapping with the first land in the thickness direction. In this configuration, a difference in thermal expansion coefficient is reduced between a portion of the board directly below the first land and a portion of the board directly below the second land. Therefore, it is possible to suppress the separation of the solder from the terminal of the electronic component due to the solder on the first land being pulled downward, that is, toward the board in a reflow step after several times.

Hereinafter, multiple embodiments will be described with reference to the drawings. The same or corresponding elements will be denoted by the same reference numerals throughout the embodiments, and descriptions thereof will not be repeated. When only part of the configuration is described in each embodiment, the configuration of the other preceding embodiments can be applied to other parts of the configuration. Further, not only the combinations of the configurations explicitly shown in the description of the respective embodiments, but also the configurations of the multiple embodiments can be partially combined even when they are not explicitly shown as long as there is no difficulty in the combination in particular.

### First Embodiment

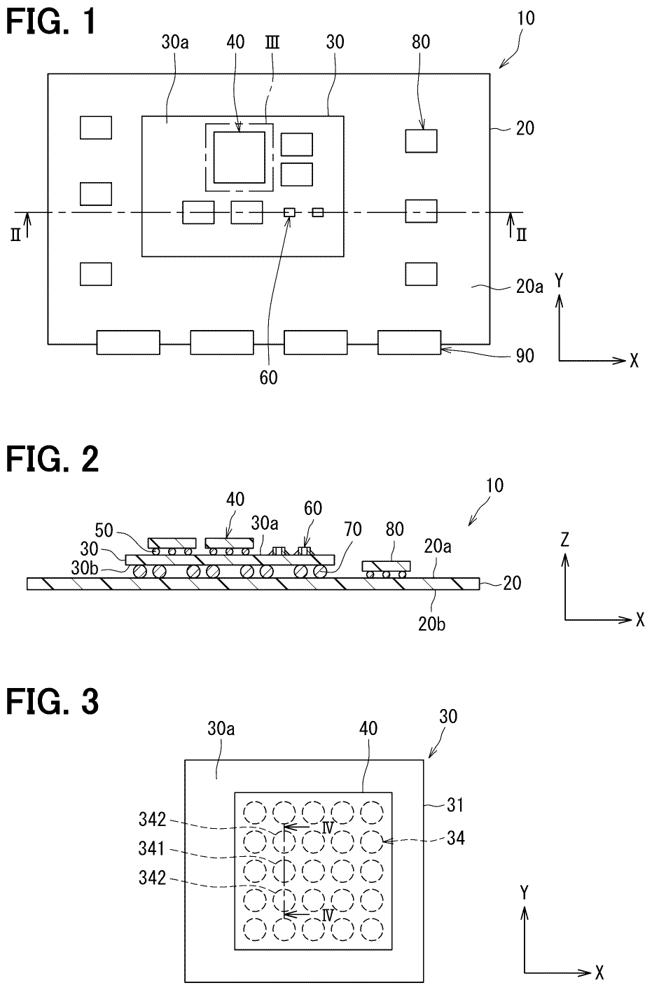

First, a schematic configuration of an electronic device will be described with reference to FIGS. 1 and 2.

### Electronic Device

FIG. 1 is a plan view showing an example of an electronic device. FIG. 2 is a cross-sectional view of the semiconductor device taken along a line II-II in FIG. 1. For the sake of simplicity, conductors of a board and some of terminals of electronic components are omitted in FIG. 2.

Hereinafter, a thickness direction of a sub board is referred to as a Z direction. A direction perpendicular to the Z direction is referred to as an X direction, and a direction perpendicular to both of the Z direction and the X direction is referred to as a Y direction. Unless otherwise specified, a shape of an element when viewed along the Z direction, that is, a shape of an element along an XY plane including the X direction and the Y direction will be referred to as a planar shape or a shape in a plan view. The plan view of an element when viewed along the Z direction may be simply referred to as a plan view.

An electronic device 10 shown in FIGS. 1 and 2 includes a main board 20, a sub board 30, an electronic component 40, and solder 50. The electronic device 10 may further include a housing (not shown). The housing accommodates the main board 20, the sub board 30, the electronic component 40, and the like. The electronic device 10 has, for example, a predetermined control function. Such an electronic device 10 is sometimes referred to as an electronic control unit (ECU).

The main board 20 and the sub board 30 may be referred to as boards, printed boards, wiring boards, or the like. The sub board 30 is mounted on the main board 20. For this reason, the main board 20 is sometimes referred to as a mother board. The thickness direction of the main board 20 is approximately parallel to the Z direction. The main board 20 has a first surface 20a and a second surface 20b. The first surface 20a is a surface on one end side in the Z direction, and the second surface 20b is a surface on the other end side in the Z direction. In other words, the second surface 20b is a back surface opposite to the first surface 20a in the Z direction. The sub board 30 is disposed on the first surface 20a. The planar shape of the main board 20 is not particularly limited. In the present embodiment, as an example, the main board 20 has a generally rectangular shape in the plan view with the X direction as a longitudinal or lengthwise direction. In the plan view, the main board 20 encloses the sub board 30 therein.

The thickness direction of the sub board 30 is the Z direction. The sub board 30 has a first surface 30a and a second surface 30b. The first surface 30a is a surface on one end side in the Z direction, and the second surface 30b is a surface on the other end side in the Z direction. In other words, the second surface 30b is a back surface opposite to the first surface 30a in the Z direction. The second surface 30b is a surface that faces the first surface 20a of the main board 20 in the Z direction. The planar shape of the sub board 30 is not particularly limited. In the present embodiment, as an example, the sub board 30 has a generally rectangular shape in the plan view with the X direction as the longitudinal or lengthwise direction. In the plan view, the size of the sub board 30 is smaller than the size of the main board 20. In the plan view, the sub board 30 is entirely enclosed in the main board 20.

The sub board 30 is stacked on the main board 20. The stacking direction of the sub board 30 and the main board 20 is approximately parallel to the Z direction. The electronic component 40 is disposed on the first surface 30a of the sub board 30. The electronic component 40 is connected to the sub board 30 via the solder 50. Although details will be described later, the electronic component 40 is an electronic component that has a plurality of terminals on the surface facing the sub board 30. The solder 50 joins the terminals of the electronic component 40 to lands of the sub board 30.

The electronic device 10 includes at least one electronic component 40, as electronic component(s) mounted on the sub board 30. In the present embodiment, as an example, the electronic device 10 includes multiple electronic components 40. The electronic device 10 further includes electronic components 60. The electronic components 60 are mounted on the sub board 30, and are electronic components other than the electronic components 40 on the sub board 30. The electronic components 60 have different structures from the electronic components 40. The electronic components 60 are disposed on the first surface 30a of the sub board 30 together with the electronic components 40.

The illustrated electronic device 10 further includes solder 70, an electronic component 80, and a connector 90. The solder 70 joins the sub board 30 and the main board 20 to each other, for example. The solder 70 joins lands disposed on the second surface 30b of the sub board 30 to lands disposed on the first surface 20a of the main board 20. The electronic component 80 and the connector 90 are mounted on the main board 20 together with the sub board 30. The electronic component 80 and the connector 90 are joined to the lands of the main board 20 via the solder 70, for example.

The connector 90 is mounted on the main board 20 in order to electrically connect the circuits configured in the electronic device 10 to the outside of the electronic device 10 (e.g., external devices). In the present embodiment, as an example, the connector 90 electrically connects the circuits formed by the main board 20, the sub board 30, and the electronic components 40, 60, and 80 to the external devices.

In the illustrated electronic device 10, at least one of the electronic components 40 includes processing circuitry including a processor, memory, storage, and the like. The processor accesses the memory to execute various processes for implementing respective functions. The memory is, for example, a random access memory (RAM). The storage includes a non-volatile storage medium such as a flash memory. The storage stores a control program executed by the processor. The circuits configured by the sub board 30 and the electronic components 40 and 60 provide predetermined control functions. The circuits configured by the main board 20 and the electronic components 80 provide, for example, a power supply circuit for supplying operation power to the circuits configured by the sub board 30 and the electronic components 40 and 60, a communication interface, and the like.

### Sub Board, Electronic Components, and Mounting Structure

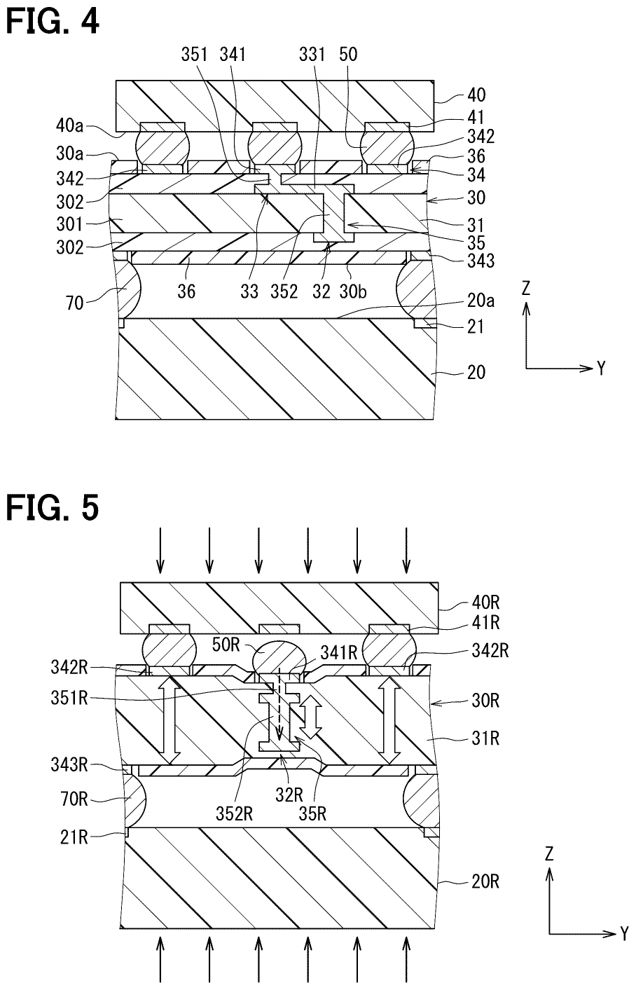

FIG. 3 is an enlarged view of a region Ill indicated by the dashed line in FIG. 1. FIG. 4 is a cross-sectional view taken along a line IV-IV in FIG. 3. FIGS. 3 and 4 show the arrangement area of the electronic component 40 and its surrounding area.

The sub board 30 includes an insulating base 31 and a conductor 32. The insulating base 31 is made of an electrically insulating material such as resin. The conductor 32 is disposed on the insulating base 31. The conductor 32 is made of a metal material, such as copper (Cu), having favorable electrical conductivity. The conductor 32 has a wiring 33 including a land 34 and a via hole 35. The conductor 32 includes at least a conductor that provides a wiring function (circuit function). The conductor 32 may include a conductor that do not provide a wiring function, such as a conductor for heat dissipation, or the like. The sub board 30 further includes a solder resist 36. The solder resist 36 is disposed on both surfaces of the insulating base 31 in the Z direction.

The wiring 33 is arranged in multiple layers on the insulating base 31. In other words, the sub board 30 is a multi-layer board. The wiring 33 includes an inner layer wiring 331 arranged inside the insulating base 31 and a surface wiring arranged on the surface of the insulating base 31. The wiring 33 is formed, for example, by patterning a metal foil. The wiring 33 may be referred to as a wiring pattern, a conductor pattern, or the like.

The land 34 is a part of the wiring 33 (surface wiring), and is disposed on the surface of the insulating base 31. In FIG. 4, of the surface wiring, only the land 34 is shown. The land 34 is a part of the surface wiring that is exposed from the solder resist 36. The other parts of the surface wiring are covered with the solder resist 36. The positional relationship between the land 34 and the solder resist 36 may be that of a normal resist or an over resist.

The via hole 35 is connected to the wiring 33 including the land 34. The via hole 35 corresponds to an interlayer connection portion. The via hole 35, which forms a circuit, electrically connects the wirings 33 arranged on different layers. The via hole 35 is formed, for example, by arranging a conductor in a hole formed in the insulating base 31 by metal plating or the like. The via hole 35 is also referred to as a via conductor. The via hole 35 may be a penetrating via (through-hole via) that penetrates the insulating base 31 in the Z direction, or may be a non-penetrating via. The via hole 35 may penetrate one (single layer) of insulating layers constituting the insulating base 31, or may penetrate a plurality of insulating layers (multiple layers). In the via hole 35, the conductor may be provided only on the wall surface of the hole, or may be provided so as to fill the hole. The via hole 35 may have a configuration in which a conductor is disposed on the wall surface of the hole and the gap is filled with resin. For the sake of convenience, in the cross-sectional views in FIG. 4 and subsequent figures, the via hole 35 in which the illustration of the gap is omitted is shown.

The electronic component 40 is an IC package. For example, the electronic component 40 includes an IC chip, wiring members, a sealing body, and the like (not shown). The electronic component 40 is a surface mount-type component. The electronic component 40 has multiple terminals 41 on a facing surface 40a that faces the sub board 30. The terminals 41 are arranged in a matrix on the facing surface 40a. The terminals 41 are aligned in the X and Y directions. The electronic component 40 is, for example, a BGA, an LGA, or the like. BGA is an abbreviation for ball grid array. LGA is an abbreviation for land grid array. In the case of the BGA, the electronic component 40 includes ball-shaped solders 50. The solders 50 are provided individually for the respective terminals 41.

The lands 34 connected to the terminals 41 via the solders 50 are arranged in a matrix corresponding to the terminals 41. The multiple lands 34 are aligned in the X and Y directions. The lands 34 connected to the terminals 41 include lands 341 and 342 arranged on the first surface 30a. The land 341 is a land to which the via hole 35 is electrically connected. The multiple lands 34 connected to one electronic component 40 include at least one land 341. The multiple lands 34 connected to one electronic component 40 may include only one land 341 or may include multiple lands 341.

The land 342 is disposed next to the land 341, and no via hole 35 is disposed directly below the land 342 in the plan view, that is, in the thickness direction. No via hole 35 is arranged in the area overlapping with the land 342 in the plan view. The multiple lands 34 connected to one electronic component 40 include at least one land 342. The multiple lands 34 connected to one electronic component 40 may include only one land 342 or multiple lands 342. The land 341 corresponds to a first land, and the land 342 corresponds to a second land.

In the present embodiment, as an example, lands 342 are disposed on both sides of one land 341 in the Y direction, as shown in FIGS. 3 and 4. Alternatively, the lands 342 may be disposed on both sides of the land 341 in the X direction. Further, the lands 342 may be disposed on both sides of the land 341 in the X direction as well as in the Y direction. The lands 34 connected to the terminals 41 may include a land to which no via hole 35 is electrically connected and that is not located next to the land 341 in the X and Y directions. For example, lands to which no via holes 35 are connected may be disposed adjacent to each other. The lands 34 connected to the terminals 41 may include a non-connection land that does not provide a wiring function.

The sub board 30 is a build-up board having a core layer 301 and a build-up layer 302 stacked on the core layer 301. The number of layers in the build-up board is not particularly limited. The number of build-up layer(s) 302 is not particularly limited. In FIG. 4, for the sake of convenience, one build-up layer 302 is indicated on each side of the core layer 301.

The build-up layer 302 is provided with an LVH 351, which is the via hole 35. LVH is an abbreviation for laser via hole. The LVH 351 that is provided in the build-up layer 302 forming the surface layer on the side of the first surface 30a is connected to the land 341. The LVH 351 connects to the land 341. The LVH 351 is disposed at a position overlapping at least a portion of the land 341 in the plan view. The LVH 351 is disposed directly below the land 341. In the present embodiment, as an example, the LVH 351 is enclosed in the land 341 in the plan view.

The core layer 301 is provided with an IVH 352, which is the via hole 35. IVH is an abbreviation for inner via hole. The IVH 352 penetrates the core layer 301. The IVH 352 is disposed at a position that does not overlap the land 341 in the plan view. The IVH 352 is offset from the land 341 in the plan view. The IVH 352 is offset from the LVH 351 in the plan view. The inner layer wirings 331 are connected to both ends of the IVH 352 in the Z direction. The IVH 352 is connected to the land 341 via the inner layer wiring 331 and the LVH 351. In the present embodiment, as an example, the IVH 352 is offset from the land 341 and the LVH 351 in the Y direction. The inner layer wiring 331 interposed between the IVH 352 and the LVH 351 extends in the Y direction. The IVH 352 is connected to the vicinity of one of the ends of the inner layer wiring 331, and the LVH 351 is connected to the vicinity of the other end of the inner layer wiring 331.

At least one of the lands 342 may be connected to a surface wiring (not shown). At least one of the lands 342 may be a land to which no via hole 35 is electrically connected. At least one of the lands 342 may be electrically connected to the via hole 35 through a surface wiring. In this case, the via hole 35 electrically connected to the land 342 is disposed at a position that does not overlap the land 342 in the plan view. At least one of the lands 342 may be a non-connection land.

The lands 34 include a land 343 disposed on the second surface 30b. The land 343 is connected to a land 21 of the main board 20 via the solder 70. The main board 20 has a similar configuration to the sub board 30. The land 21 is disposed on the first surface 20a of the main board 20. The land 21 is exposed from a solder resist (not shown). In the cross-sectional views in FIG. 4 and subsequent figures, as conductors of the main board 20, only the lands 21 are shown for the sake of convenience. In addition, the solder resist on the main board 20 is omitted. The arrangement of the lands 21 and 343 shown in FIG. 4 is merely one example. The positions of the lands 21 and 343 are not particularly limited by the positions of the lands 341 and 342.

### Summary of First Embodiment

FIG. 5 shows a reference example. FIG. 5 corresponds to FIG. 4. FIG. 5 shows a reflow step on multiple times, which is in a manufacturing process of the electronic device shown in the reference example. FIG. 5 shows the state in the reflow step after multiple times. In the reference example, the reference numerals of the elements related to the present embodiment are indicated with R as a suffix. For the sake of convenience, the build-up board is shown in a simplified manner in FIG. 5.

As shown in FIG. 5, a sub board 30R of the reference example has lands 341R and 342R, similar to the configuration shown in the present embodiment (see FIGS. 3 and 4). The lands 342R are disposed on both sides of the land 341R in the Y direction. A via hole 35R is electrically connected to the land 341R. The via hole 35R includes an LVH 351R connecting to the land 341R, and an IVH 352R connected to the land 341R via the LVH 351R. The LVH 351R and the IVH 352R are located directly below the corresponding land 341R. The LVH 351R and the IVH 352R are disposed at positions overlapping the land 341R in the plan view. No via hole 35R is disposed directly below the land 342R.

The electronic component 40R is mounted on the sub board 30R by the reflow step on the first time. The sub board 30R having the electronic component 40R thereon is mounted on the main board 20R by the reflow step on a several time, such as on the second time. The solid arrows in FIG. 5 indicate heat (hot air and radiant heat) applied in the reflow step on a several time. During the reflow, heat, hot air and radiant heat are applied to both sides in the Z direction.

In the sub board 30R, the thermal expansion coefficient in the Z direction is different between a portion directly below the land 341R in which the via hole 35R is disposed and a portion directly below the land 342R in which no via hole 35R is disposed. The resin constituting the insulating base 31R has a larger linear expansion coefficient than the conductor (e.g., copper) constituting the via hole 35R. For this reason, as shown by the hollow arrows in FIG. 5, the expansion of the sub board 30R during the reflow is larger in the portion directly below the land 342R than the portion directly below the land 341R. In other words, since the expansion is small in the portion directly below the land 341R, the solder 50R disposed on the land 341R receives a force to be pulled downward (towards the main board 20R). In other words, the opposing distance between the sub board 30R and the electronic component 40R is greater at the land 341R than at the land 342R.

Furthermore, in the reflow step after the multiple times, the solder 50R that has solidified during the previous reflow step receives heat and melts. The heat from above is transferred to the sub board 30R through the electronic component 40R. However, in the case of the land 341R, as shown by the dashed arrow in FIG. 5, the heat escapes through the land 341R to the via hole 35R side. Since there is no via hole 35R directly below the land 342R, heat is less likely to escape from the land 342R to the inside of the sub board 30R. Therefore, the melting of the solder 50R on the land 341R is delayed with respect to the melting of the solder 50R on the land 342R.

If a force that pulls the solder 50R on the land 341R downwards acts on the solder 50R on the land 341R while the solder 50R on the land 341R is still partially unmelted, there is a risk that the solder 50R will separate from the terminal 41R. In other words, the unmelted solder 50R cannot keep up with the increase in the opposing distance, and there is a risk that the separation will occur with respect to the terminal 41R. In the case of BGA, the solder separation is sometimes referred to as the ball drop.

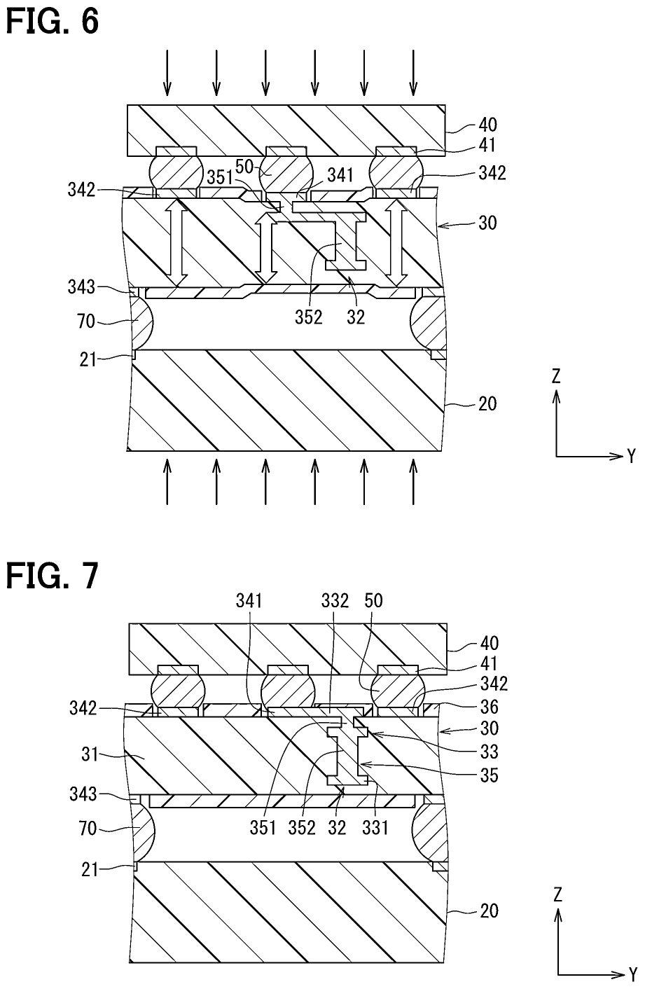

FIG. 6 shows the state of the electronic device according to the present embodiment in the reflow step after multiple times. FIG. 6 corresponds to FIG. 4. FIG. 6 shows the reflow step after multiple times. The solid arrows in FIG. 6 indicate heat (hot air and radiant heat) during the reflow step after multiple times, similar to FIG. 5 For the sake of convenience, FIG. 6 shows the build-up board in a simplified manner, similar to FIG. 5.

The via hole 35 has a large effect on the thermal expansion coefficient of the sub board 30. In the present embodiment, at least one of the via holes 35 (interlayer connection portions) electrically connected to the lands 341 (first land) is intentionally shifted to a position without overlapping the land 341 in the thickness direction. Therefore, the difference in the coefficient of thermal expansion, that is, the difference in the magnitude of thermal expansion between the portion directly below the land 341 and the portion directly below the land 342 (second land) in the sub board 30 can be reduced as shown by the hollow arrows in FIG. 6. In the configuration shown in FIG. 6, the amount of expansion of the portion directly below the land 341 approximates to the amount of expansion of the portion directly below the land 342, as compared with the configuration shown in FIG. 5. As a result, the force pulling the solder 50 on the land 341 downward is weakened during the reflow step after the multiple times. Therefore, the occurrence of solder separation at the interface with the terminal 41 of the electronic component 40 can be suppressed.

As illustrated, the lands 342 (second lands) may be disposed on both sides of the land 341 (first land) in one direction perpendicular to the Z direction (plate thickness direction). In such a configuration, the thermal expansion is large in the portions directly below the lands 342 on both sides, and the solder 50 on the land 341 located between the lands 342 is likely to be separated. However, by shifting the position of at least one of the via holes 35 to be away from the land 341, the difference in the thermal expansion coefficient between the portion directly below the land 341 and the portion directly below the land 342 can be reduced. Therefore, the separation of the solder 50 on the land 341 located between the lands 342 can be suppressed.

As illustrated, the build-up board may be used as the sub board 30. The position of the IVH 352 formed in the core layer 301 and electrically connected to the land 341 (first land) may be offset from the land 341. In the build-up board, the IVH 352 has a large effect on the thermal expansion coefficient. Therefore, by intentionally shifting the position of the IVH 352 not to overlap with the land 341, the thermal expansion coefficient of the portion directly below the land 341 can be made further closer to the thermal expansion coefficient of the portion directly below the land 342. In other words, the occurrence of solder separation can be effectively suppressed.

As illustrated, in the sub board 30 which is the build-up board, the position of the IVH 352 (first via hole) and the position of the LVH 351 (second via hole) connected to the land 341 may be offset from the land 341. In this manner, by intentionally shifting the positions of both the LVH 351 and the IVH 352 not to overlap with the land 341, the thermal expansion coefficient of the portion directly below the land 341 can be made even closer to the thermal expansion coefficient of the portion directly below the land 342.

As illustrated, the sub board 30 may be stacked on the main board 20, and the electronic component 40 may be disposed on the first surface 30a of the sub board 30 opposite the facing surface facing the main substrate 20. In such a configuration, after the electronic component 40 is mounted on the sub board 30, the sub board 30 is mounted on the main board 20 by performing the reflow step on multiple time. However, as described above, at least one of the via holes 35 electrically connected to the land 341 is intentionally shifted to a position not to overlap with the land 341. Therefore, during the reflow step on the multiple time, it is less likely that the solder 50 on the land 341 will be pulled downward, which results in the separation of the solder 50 at the interface with the terminal 41 of the electronic component 40.

### Modification

Of the via holes 35 electrically connected to the lands 341, the via hole 35 that is arranged so as not to overlap the land 341 is not limited to the IVH 352 described above. For example, as shown in FIG. 7, the position of the LVH 351 connecting to the land 341 and the position of the IVH 352 may be offset from the land 341. In such a configuration, the number of the via holes 35 disposed directly below the land 341 is reduced, as compared to the configuration shown in FIG. 6. Therefore, the thermal expansion coefficient of the portion directly below the land 341 can be made closer to the thermal expansion coefficient of the portion directly below the land 342. As such, the separation of the solder 50 on the land 341 can be more effectively suppressed.

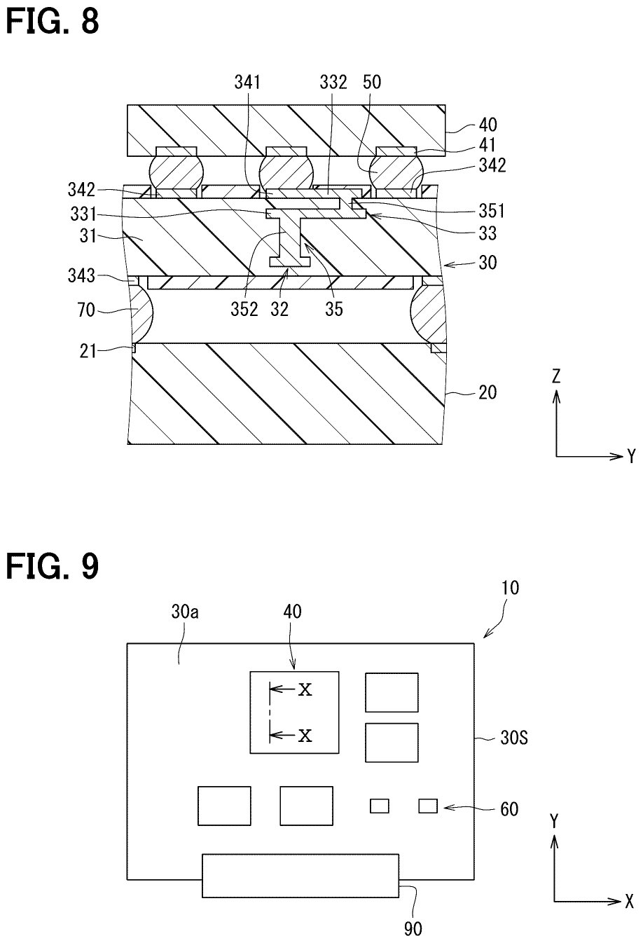

As shown in FIG. 8, the position of the LVH 351 connecting to the land 341 may be offset so as not to overlap with the land 341 in the thickness direction, and the position of the IVH 352 may be directly below the land 341. The surface wiring 332 is connected to the land 341, and the LVH 351 is electrically connected to the land 341 via the surface wiring 332. The land 341 is disposed at one end of the surface wiring 332 in the extension direction of the surface wiring 332, and the LVH 351 is connected to the other end. Also in such a configuration, it is possible to make the thermal expansion coefficient of the portion directly below the land 341 closer to the thermal expansion coefficient of the portion directly below the land 342, as compared to the reference example shown in FIG. 5. Therefore, the separation of the solder 50 on the land 341 can be suppressed.

FIG. 7 and FIG. 8 correspond to FIG. 4. In FIG. 7 and FIG. 8, for the sake of convenience, the build-up board is shown in a simplified manner, similar to FIG. 5 and FIG. 6. The sub board 30 is not limited to a build-up board. The sub board 30 may be a multi-layer board formed by stacking insulating sheets including, for example, copper foils. In such a multi-layer board, for example, the position of the via hole 35 connecting to the land 341 may be offset from the land 341 so as not to overlap with the land 341 in the plan view. The via hole 35 that is electrically connected to the land 341 and located away from the land 341 in the Z direction may be offset so as not to overlap with the land 341.

### Second Embodiment

The present embodiment is a modification of the preceding embodiment as a basic configuration and may incorporate description of the preceding embodiment. In the preceding embodiment, the position of the via hole in the sub board disposed above the main board is shifted. Alternatively, the position of the via hole may be shifted in a single board.

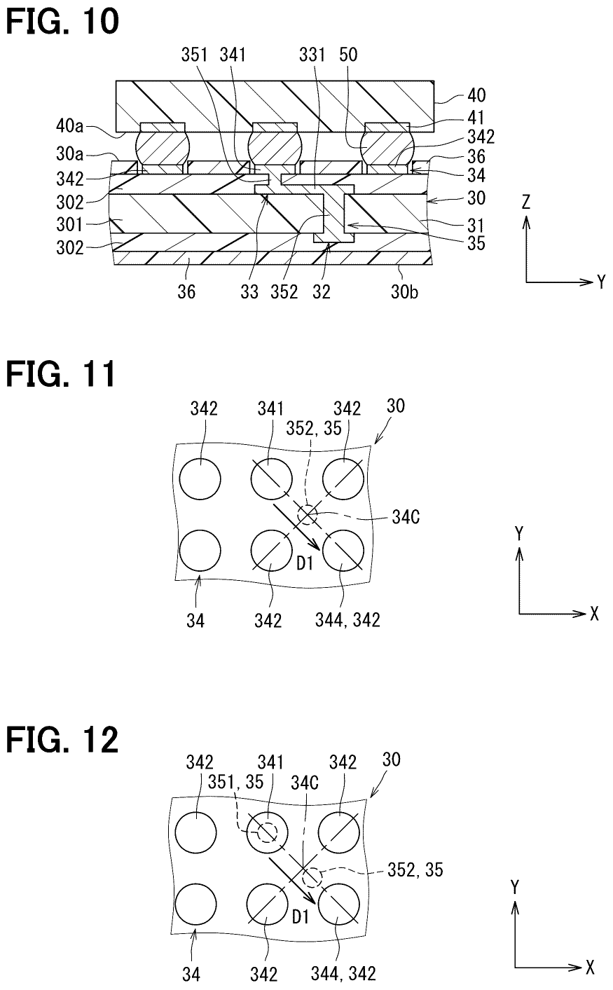

FIG. 9 shows an electronic device according to the present embodiment. For the sake of convenience, the conductors are not shown in FIG. 9. FIG. 10 is a cross-sectional view taken along a line X-X in FIG. 9.

As shown in FIGS. 9 and 10, the electronic device 10 includes a board 30S, an electronic component 40, and a solder 50. The electronic device 10 further includes an electronic component 60 and a connector 90. The electronic device 10 may include a housing (not shown). The electronic device 10 has a configuration corresponding to the configuration illustrated in the preceding embodiment (see FIGS. 3 and 4) but from which the main board 20, the solder 70, and the electronic component 80 are excluded. The connector 90 is mounted on the board 30S.

The electronic component 40 has multiple terminals 41 on a facing surface 40a that faces the board 30S. The multiple terminals 41 are arranged in a matrix on the facing surface 40a. The multiple terminals 41 are aligned in the X direction and the Y direction.

The board 30S is not mounted on another board. The board 30S has a similar configuration to the sub board 30. The thickness direction of the board 30S corresponds to the Z direction. The board 30S has a first surface 30a and a second surface 30b. In the present embodiment, as an example, the board 30S has a generally rectangular shape in the plan view with the X direction as the longitudinal direction.

The board 30S includes an insulating base 31 and a conductor 32. The conductor 32 has a wiring 33 including a land 34 and a via hole 35. The wiring 33 is arranged in multiple layers on the insulating base 31. The wiring 33 include a surface wiring (not shown) arranged on the surface of the insulating base 31 and an inner layer wiring 331 arranged inside the insulating base 31.

The lands 34 connected to the terminals 41 via the solders 50 are arranged in a matrix corresponding to the terminals 41. The lands 34 are aligned in the X direction and the Y direction. The lands 34 connected to the terminals 41 include lands 341 and 342 arranged on the first surface 30a. Similar to the preceding embodiment, the land 341 is one of the multiple lands 34 and is electrically connected to the via hole 35. The land 342 is disposed next to the land 341, and no via hole 35 is disposed directly below the land 342 in the plan view. The lands 34 include a land 343 disposed on the second surface 30b.

In the present embodiment, as an example, the lands 342 are arranged on both sides of one land 341 in the Y direction. The board 30S is a build-up board. The via hole 35 includes the IVH 351 and the LVH 352. The LVH 351 that is formed in the build-up layer 302 and connects to the land 341 is disposed directly below the land 341, similar to the configuration shown in the preceding embodiment (see FIG. 4). The IVH 352 that is formed in the core layer 301 is disposed at a position that does not overlap with the land 341 in the plan view. The IVH 352 is connected to the land 341 via the inner layer wiring 331 and the LVH 351. Other configurations are similar to those described in the preceding embodiment.

### Summary of Second Embodiment

In the configuration having the single board 30S, the reflow may be performed multiple times due to double-sided mounting of the electronic components or the like. In the present embodiment, in the board 30S, at least one of the via holes 35 (interlayer connection portions) electrically connected to the lands 341 (first lands) is intentionally shifted to the position that does not overlap with the land 341. In this case, it is possible to reduce the difference in the coefficient of thermal expansion, that is, the difference in the magnitude of thermal expansion between the portion directly below the land 341 and the portion directly below the land 342 (second land) in the board 30S. Therefore, the similar effects to those of the configurations shown in the preceding embodiment can be achieved. In other words, it is less likely that the solder 50 on the land 341 will be pulled downward during the reflow step on multiple time, and thus it is possible to suppress the occurrence of solder separation at the interface with the terminal 41 of the electronic component 40.

As illustrated, the lands 342 (second lands) may be disposed on both sides of the land 341 (first land) in one direction perpendicular to the Z direction (plate thickness direction). As illustrated, the build-up board may be used as the board 30S, and the position of the IVH 352 may be offset from the land 341. These configurations are similar to the configurations of the sub board 30 shown in the preceding embodiment. Therefore, it is possible to achieve the similar effects to those described in the preceding embodiment.

The configuration of the board 30S is not limited to the example shown in FIG. 10. For example, the via hole 35 of the board 30S may have the arrangement shown in FIG. 7 or FIG. 8. For example, in the board 30S which is the build-up board, the position of the IVH 352 (first via hole) and the position of the LVH 351 (second via hole) connecting to the land 341 may be offset from the land 341. The board 30S is not limited to the build-up board.

### Third Embodiment

The present embodiment is a modification of the preceding embodiment(s) as a basic configuration and may incorporate description of the preceding embodiment(s). In the preceding embodiment, the position of the via hole is shifted in the direction along row or column of the matrix. Alternatively, the position of the via hole may be shifted in a diagonal direction.

FIG. 11 shows a sub board in the electronic device according to the present embodiment. FIG. 11 shows a part of the sub board on which the electronic component is arranged. In FIG. 11, illustration of the electronic component is omitted. The basic configuration of the electronic device 10 is similar to that shown in the preceding embodiment (see FIGS. 3 and 4). A sub board 30 is mounted on a main board 20. An electronic component 40 is disposed on a first surface 30a of the sub board 30.

The sub board 30 has the lands 34 arranged in a matrix corresponding to the terminals 41 of the electronic component 40, similar to the configuration shown in the preceding embodiment. The multiple lands 34 are arranged in a matrix with a predetermined pitch. The lands 34 are arranged at a predetermined pitch in the X direction and are also arranged at a predetermined pitch in the Y direction. One of the X and Y directions corresponds to the row direction, and the other corresponds to the column direction. The lands 34 includes the land 341 and the land 342.

At least one of the via holes 35 electrically connected to the lands 341 is disposed at a position offset from the land 341 in the diagonal direction (direction D1) of the matrix arrangement. The diagonal direction with respect to the land 341 is a direction connecting the land 341 and the land 344 located diagonally to the land 341 in an imaginary quadrilateral (square) formed by the four lands 34 including the land 341. At least one of the via holes 351 is disposed on an imaginary line connecting the centers of the lands 341 and 344 in the plan view. At least one of the via holes 351 is shifted toward the land 344 with respect to the land 341.

In the present embodiment, as an example, the IVH 352 as the via hole 35 is disposed on the imaginary line indicated by the dashed line. The IVH 352 is provided at a center position 34C between the land 341 and the land 344 in the diagonal direction. The center position 34C is the center position of an imaginary quadrilateral formed by the four lands 34 including the lands 341 and 344. Furthermore, the lands 342 are disposed next to the land 341 in the X and Y directions. The land 344 is not particularly limited. In the example shown in FIG. 11, the land 344 is the land 342. The land 344 may be a land different from the land 342. As shown in the preceding embodiment, the land 342 only needs to be located next to the land 341 in one direction. The land 344 may be, for example, the land 341 or the non-connection land. Other configurations are similar to those described in the preceding embodiment.

### Summary of Third Embodiment

As illustrated in the present embodiment, the multiple lands 34 corresponding to the terminals 41 of the electronic component 40 may be arranged in a matrix at a predetermined pitch. In this configuration, at least one of the via holes 35 (interlayer connection portions) electrically connected to the land 341 (first land) may be intentionally shifted in a diagonal direction of the matrix arrangement with respect to the land 341. The distance between the via hole 35 and the land 341 can be made longer as compared with a configuration in which the via hole 35 is shifted in a direction along the row or column of the matrix arrangement. In other words, the via hole 35 can be located away from the land 341. Therefore, the thermal expansion coefficient of the portion directly below the land 341 can be made even closer to the thermal expansion coefficient of the portion directly below the land 342 (second land). As such, it is possible to effectively suppress the separation of the solder 50 at the interface with the terminal 41 of the electronic component 40 due to the solder 50 on the land 341 being pulled downward during the reflow after multiple times.

As illustrated, at least one of the via holes 35 electrically connected to the land 341 may be disposed at a center position 34C between the land 341 and the land 344 located diagonally next to the land 341. In the plan view, the center position of the via hole 35 may substantially coincide with the center position 34C.

When the pitch of the lands 34 in the direction along the row or column of the matrix arrangement is defined as L, and the distance from the center of the land 341 to the center of the via hole 35 (e.g., the center of the IVH 352) is defined as R, the distance R is the length obtained by dividing the pitch L by the square root of 2 (√2). In the case where the via hole 35 is disposed at the center position between the lands 34 in the direction along the row or column of the matrix arrangement, the distance R is half the length of the pitch L. By arranging the via hole 35 at the diagonal center position 34C, the via hole 35 can be equidistant from the lands 341 and 344 while increasing the distance between the via hole 35 and each of the lands 341 and 344. Therefore, it is possible to effectively suppress the separation of the solder 50 on the land 341 while suppressing the influence of the via hole 35 on the surrounding land 344.

### Modification

The arrangement of the via hole 35 is not limited to the arrangement shown in FIG. 11. For example, as shown in FIG. 12, at least one of the via holes 35 may be provided on an imaginary line connecting the centers of the lands 341 and 344, but at a position offset from the center position 34C. FIG. 12 corresponds to FIG. 11. In FIG. 12, the land 344 is the land 342 without having the via hole 35 disposed directly below. For this reason, the via hole 35 (the IVH 352) is offset toward the land 344 from the center position 34C. Although not shown, the via hole 35 may be offset toward the land 341 from the center position 34C. In FIG. 12, the LVH 351 is disposed directly below the land 341.

The via hole 35 that is shifted in position with respect to the land 341 is not limited to the IVH 352. As shown in the preceding embodiment, the LVH 351 and the IVH 352 may be shifted, or only the LVH 351 may be shifted. The sub board 30 is not limited to the build-up board. The above-described configuration may be applied to the board 30S instead of the sub board 30

### Fourth Embodiment

The present embodiment is a modification of the preceding embodiment(s) as a basic configuration and may incorporate description of the preceding embodiment(s). In the preceding embodiment(s), the positions of the via holes are shifted within a range where they overlap with the electronic components in the plan view. In addition, the via holes may be shifted to positions without overlapping with the electronic component.

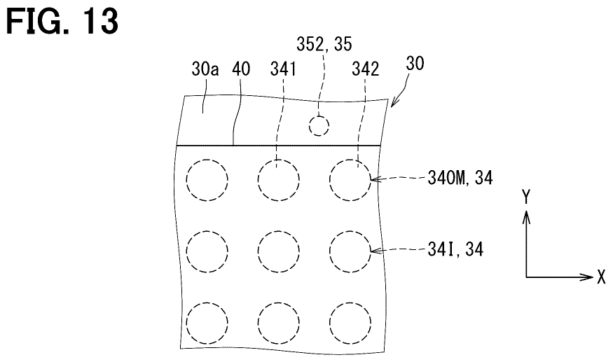

FIG. 13 shows a sub board in the electronic device according to the present embodiment. FIG. 13 shows the periphery of a portion of the sub board where the electronic component is arranged. The basic configuration of the electronic device 10 is similar to that shown in the preceding embodiment(s) (see FIGS. 3 and 4). The sub board 30 is mounted on the main board 20. Multiple electronic components 40 are arranged on the first surface 30a of the sub board 30.

As shown in FIG. 13, at least one of the via holes 35 electrically connected to the land 341 is disposed at a position that does not overlap with the electronic component 40 in the plan view. That is, at least one of the via holes 35 is disposed outside the electronic component 40. As an example, the sub board 30 of the present embodiment is a build-up board. Of the via holes 35 electrically connected to the lands 341, the IVH 352 is disposed outside the electronic component 40.

The sub board 30 has the lands 34 arranged in a matrix corresponding to the terminals 41 of the electronic components 40, similar to the configuration shown in the preceding embodiment(s). The lands 34 are aligned in the X direction and the Y direction. The lands 34 include lands 34OM arranged on the outermost periphery and lands 341 arranged next to and on the inner side of the lands 34OM on the outermost periphery. The land 341 is the land disposed in the vicinity of the land 34OM. In the following, the land 34OM may be also referred to as the outermost land, and the land 341 may be referred to as the nearby land.

At least one of the outermost lands 34OM or the nearby lands 341 includes the land 341. That is, the outermost lands 34OM may include the land 341, or the nearby lands 341 may include the land 341. Both the outermost lands 34OM and the nearby lands 341 may include the lands 341. In the present embodiment, as an example, the outermost lands 34OM include the land 341. The IVH 352 is disposed at a position offset from the lands 341 disposed on the outermost periphery. The outermost lands 34OM also include the land 342. The land 342 is disposed next to the land 341 on the outermost periphery. Other configurations are similar to those described in the preceding embodiment(s).

### Summary of Fourth Embodiment

As illustrated in the present embodiment, at least one of the via holes 35 (interlayer connection portions) electrically connected to the land 341 (first land) may be shifted to a position not to overlap with the electronic component 40 in the plan view. By arranging the at least one of the via holes 35 outside of the electronic component 40, the distance from the land 341 can be increased. For example, it is possible to place the via hole 35 farther away from the land 341 than in a configuration in which the position of the via hole 35 is shifted within a range overlapping with the electronic component 40. Therefore, it is possible to effectively restrict the occurrence of solder separation at the interface with the terminal 41 of the electronic component 40.

As illustrated, the multiple lands 34 corresponding to the terminals 41 of the electronic component 40 may be arranged in a matrix. In such a configuration, at least one of the outermost lands 34OM or the nearby lands 341 may include the land 341. The outermost lands 34OM and the nearby lands 341 are close to the outer peripheral edge of the electronic component 40 in the plan view. Therefore, it is easy to draw wirings from the lands 341 arranged on the outermost periphery or on the inner side of the outermost periphery by one land to the outside of the electronic component 40. In other words, the position of the via hole 35 can be easily shifted outside the electronic component 40.

The via hole 35 that is shifted in position with respect to the land 341 is not limited to the IVH 352. As illustrated in the preceding embodiment(s), the LVH 351 and the IVH 352 may be shifted, or only the LVH 351 may be shifted. The sub board 30 is not limited to a build-up board. The above-described configuration may be applied to the board 30S instead of the sub board 30.

### Other Embodiments

The disclosure in the specification, the drawings and the like is not limited to the embodiments exemplified hereinabove. The present disclosure encompasses the exemplified embodiments and modifications thereof by those skilled in the art. For example, the present disclosure is not limited to the parts and/or combinations of elements shown in the embodiments. The present disclosure may be implemented by various combinations thereof. The present disclosure may have additional parts that may be added to the embodiments. The present disclosure encompasses modifications in which components and/or elements are omitted from the embodiments. The present disclosure encompasses the replacement or combination of components and/or elements between one embodiment and another. The technical scopes disclosed in the present disclosure are not limited to the description of the embodiments. It should be understood that a part of disclosed technical scopes are indicated by claims, and the present disclosure further includes modifications within an equivalent scope of the claims.

The disclosure in the description, the drawings, and the like is not limited by the description of the scope of claims. The disclosure in the specification, the drawings, and the like encompasses the technical ideas described in the claims, and further extends to a wider variety of technical ideas than those in the claims. Thus, various technical ideas can be extracted from the disclosure of the description, the drawings, and the like without being restricted by the description of the scope of claims.

When an element or a layer is described as “disposed above” or “coupled”, “connected”, the element or the layer may be disposed directly above or coupled to or connected to another element or another layer, or an intervening element or an intervening layer may be present therebetween. In contrast, when an element is described as “disposed directly on,” “directly coupled to,” “directly connected to”, or “directly combined with” another element or another layer, there are no intervening elements or layers present. Other terms used to describe the relationships between elements (for example, “between” vs. “directly between”, and “adjacent” vs. “directly adjacent”) should be interpreted similarly. In the present specification, when an element is described as “disposed directly below another element”, it can mean that the element is disposed at a position corresponding to another element in the thickness direction of the board, and an intervening element or layer may present therebetween. As used herein, the term “and/or” includes any combination and all combinations relating to one or more of the related listed items. For example, the term A and/or B includes only A, only B, or both A and B. That is, a reference to A and/or B means at least one of A and B.

Spatial relative terms “inside”, “outside”, “back”, “bottom”, “low”, “top”, “high”, or the like are used herein to facilitate the description that describes relationships between one element or feature and another element or feature. Spatial relative terms can be intended to include different orientations of a device in use or operation, in addition to the orientations illustrated in the drawings. For example, when a device in a drawing is turned over, elements described as “below” or “directly below” other elements or features are oriented “above” the other elements or features. Therefore, the term “below” can include both above and below. The device may be oriented in another direction (rotated 90 degrees or in any other direction) and the spatially relative terms used herein are interpreted accordingly.

For example, some or all of the functions of the processor may be realized as hardware. A form in which a certain function is realized as hardware includes a form in which the function is realized using one or more ICs or the like. The processor may be a CPU, an MPU, a GPU, a DFP, or the like. CPU is an abbreviation for central processing unit. MPU is an abbreviation for micro-processing unit. GPU is an abbreviation for graphics processing unit. DFP is an abbreviation for data flow processor.

Some or all of the functions of the processor may be realized by combining multiple types of arithmetic processing devices. Some or all of the functions of the processor may be realized using a SoC, an ASIC, an FPGA, or the like. SoC is an abbreviation for system on chip. ASIC is an abbreviation for application specific integrated circuit. FPGA is an abbreviation for field programmable gate array.

A control program may be stored in a computer-readable non-transitory tangible storage medium as an instruction executed by a computer. The storage medium for the control program may be the above-mentioned flash memory, or may be a ROM, HDD, SSD, or the like. ROM is abbreviation for read only memory. HDD is an abbreviation for hard disk drive. SSD is an abbreviation for solid state drive.

What is claimed is:

1. An electronic device comprising:
a board having a plurality of lands disposed on a surface thereof;
an electronic component disposed on the board and having a plurality of terminals on a surface facing the surface of the board, the plurality of terminals being correspondingly provided for the plurality of lands;
a solder disposed between the plurality of lands and the plurality of terminals to bond therebetween, wherein
the board includes an insulating base and a plurality of conductors disposed on the insulating base, the plurality of conductors including the plurality of lands, a plurality of wirings disposed in layers, and a plurality of interlayer connection portions electrically connecting the plurality of wirings on different layers,
the plurality of lands includes a first land to which the interlayer connection portions are electrically connected and a second land that is disposed adjacent to the first land and at a position below which no interlayer connection portion is disposed in a thickness direction of the board, and
the interlayer connection portions electrically connected to the first land includes at least one interlayer connection portion that is disposed at a position offset from the first land so as not to overlap with the first land in the thickness direction.

2. The electronic device according to claim 1, wherein
the plurality of lands includes at least two second lands disposed on both sides of the first land in a direction orthogonal to the thickness direction.

3. The electronic device according to claim 1, wherein
the board is a build-up board including a core layer and a build-up layer stacked on the core layer,
the interlayer connection portions electrically connected to the first land includes a via hole penetrating the core layer, and
the via hole is disposed at a position offset from the first land so as not to overlap with the first land in the thickness direction.

4. The electronic device according to claim 3, wherein
the via hole penetrating the core layer is a first via hole,
the interlayer connection portions electrically connected to the first land includes, in addition to the first via hole, a second via hole that is disposed in the build-up layer and connects to the first land, and
the first via hole and the second via hole are disposed at positions offset from the first land so as not to overlap with the first land in the thickness direction.

5. The electronic device according to claim 1, wherein
the interlayer connection portions electrically connected to the first land includes a via hole that connects to the first land, and
the via hole is disposed at a position offset from the first land so as not to overlap with the first land in the thickness direction.

6. The electronic device according to claim 1, wherein
the plurality of lands correspondingly provided to the plurality of terminals is arranged in a matrix at a predetermined pitch, and
the interlayer connection portions electrically connected to the first land includes at least one interlayer connection portion that is disposed at a position offset from the first land in a diagonal direction of the matrix.

7. The electronic device according to claim 6, wherein
the at least one interlayer connection portion is disposed at a central position between the first land and another land adjacent to the first land in the diagonal direction.

8. The electronic device according to claim 1, wherein
the plurality of interlayer connection portions electrically connected to the first land includes at least one interlayer connection portion that is disposed at a position offset from the electronic component so as not to overlap with the electronic component in the thickness direction.

9. The electronic device according to claim 8, wherein
the plurality of lands correspondingly provided for the plurality of terminals is arranged in a matrix, and
at least one of outermost lands disposed on an outermost periphery of the matrix or nearby lands disposed next to the outermost lands on an inner side thereof includes the first land.

10. The electronic device according to claim 1, wherein
the board is a sub board,
the electronic device further comprising:
a main board, wherein
the sub board is stacked on the main board, and
the electronic component is disposed on a surface of the sub board opposite to the main board in the thickness direction.
